(19) United States
(12) Patent Application Publication
(10) Pub. No.: US 2025/0373243 A1
(43) Pub. Date: Dec. 4, 2025

(54) SEMICONDUCTOR DEVICE

(71) Applicant: Mitsubishi Electric Corporation, Tokyo (JP)

(72) Inventor: Keisuke KAWAMOTO, Tokyo (JP)

(73) Assignee: Mitsubishi Electric Corporation, Tokyo (JP)

(21) Appl. No.: 19/074,530

(22) Filed: Mar. 10, 2025

(30) Foreign Application Priority Data
May 29, 2024 (JP) 2024-086889

(51) Int. Cl. H03K 17/16

(52) U.S. Cl. CPC H03K 17/168; H03K 17/162

(57) ABSTRACT

A semiconductor device includes a parallel circuit of a MOSFET as a unipolar switching element and an IGBT as a bipolar switching element. The IGBT as the bipolar switching element has a greater chip size than the MOSFET as the unipolar switching element.

### BACKGROUND

### Technical Field

The present disclosure relates to semiconductor devices and, in particular, to a semiconductor device including a parallel circuit of a unipolar switching element and a bipolar switching element.

### Description of the Background Art

A power control semiconductor device for use in a power converter, such as an inverter, is known. For example, Japanese Patent Application Laid-Open No. 2017-228912 discloses technology of forming a power control semiconductor device including a parallel circuit of a unipolar switching element and a bipolar switching element connected in parallel and controlling timings of turn-on and turn-off of the switching elements to reduce loss.

The technology disclosed in Japanese Patent Application Laid-Open No. 2017-228912 requires complex control, such as control to turn on the unipolar switching element and the bipolar switching element at different timings and turn off the unipolar switching element and the bipolar switching element at different timings and, further, vary the timings of turn-on and turn-off of the switching elements between a low current range and a high current range. This leads to an increase in complexity and size of a control circuit to control the switching elements.

The switching elements generate radiated noise attributable to a current change rate (dI/dt) and a voltage change rate (dV/dt) at switching. In particular, the unipolar switching element has a high switching rate, thus has high values of dI/dt and dV/dt, and generates large radiated noise. Reduction in radiated noise is a task for the semiconductor device including the parallel circuit of the unipolar switching element and the bipolar switching element.

### SUMMARY

It is an object of the present disclosure to provide technology enabling contribution to reduction in loss, radiated noise, and size of a semiconductor device.

A semiconductor device according to the present disclosure includes a parallel circuit of a unipolar switching element and a bipolar switching element. The bipolar switching element has a greater chip size than the unipolar switching element.

According to the present disclosure, contribution to reduction in loss, radiated noise, and size of the semiconductor device is enabled.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram showing a configuration of a semiconductor device according to Embodiment 1;

FIG. 2 is a sequence diagram showing results of a double pulse test of the semiconductor device according to Embodiment 1;

FIG. 3 is a sequence diagram showing results of the double pulse test of a semiconductor device according to Embodiment 2;

FIG. 4 is a sequence diagram showing results of the double pulse test of a semiconductor device according to Embodiment 3;

FIG. 5 is a sequence diagram showing results of the double pulse test of a semiconductor device according to Embodiment 4; and

FIG. 6 is a sequence diagram showing results of the double pulse test of a semiconductor device according to Embodiment 5.

### DESCRIPTION OF THE PREFERRED EMBODIMENTS

### Embodiment 1

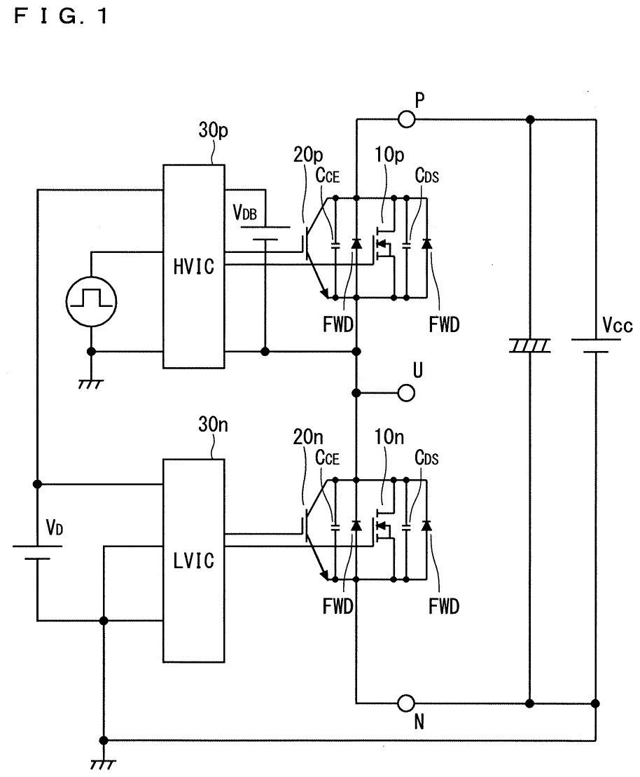

FIG. 1 is a diagram showing a configuration of a semiconductor device according to Embodiment 1. FIG. 1 shows an inverter circuit including the semiconductor device according to Embodiment 1.

The semiconductor device according to Embodiment 1 includes a parallel circuit of a unipolar switching element and a bipolar switching element connected in parallel. The inverter circuit in FIG. 1 includes the parallel circuit of the unipolar switching element and the bipolar switching element for each of a high side arm (also referred to as an “upper arm”) and a low side arm (also referred to as a “lower arm”).

That is to say, the upper arm is a parallel circuit of a metal oxide semiconductor field effect transistor (MOSFET) 10p as a unipolar switching element and an insulated gate bipolar transistor (IGBT) 20p as a bipolar switching element, and the lower arm is a parallel circuit of a MOSFET 10n as a unipolar switching element and an IGBT 20n as a bipolar switching element. FIG. 1 shows drain-source parasitic capacitances C_{DS} inherent in the MOSFETs 10p and 10n and collector-emitter parasitic capacitances C_{CE} inherent in the IGBTs 20p and 20n. A freewheeling diode FWD is connected in anti-parallel with each of the MOSFETs 10p and 10n and the IGBTs 20p and 20n. The unipolar switching element and the bipolar switching element constituting the parallel circuit are not limited to a MOSFET and an IGBT and may be any switching elements.

The MOSFET 10p and the IGBT 20p of the upper arm are driven by a high voltage integrated circuit (an HVIC) 30p as a high side control circuit, and the MOSFET 10n and the IGBT 20n of the lower arm are driven by a low voltage integrated circuit (an LVIC) 30n as a low side control circuit.

In the semiconductor device according to Embodiment 1, the bipolar switching element has a greater chip size (hereinafter simply referred to as “size”) than the unipolar switching element in each parallel circuit. That is to say, in FIG. 1, the IGBT 20p has a greater size than the MOSFET 10p, and the IGBT 20n has a greater size than the MOSFET 10n.

The MOSFETs 10p and 10n as the unipolar switching elements each have a higher switching rate than the IGBTs 20p and 20n as the bipolar switching elements. Radiated noise attributable to dI/dt and dV/dt is thus likely to increase at switching of the MOSFETs 10p and 10n. The IGBTs 20p and 20n, however, are connected in parallel with the respective MOSFETs 10p and 10n, so that the parasitic capacitances C_{CE} in the IGBTs 20p and 20n function as snubber capacitors to reduce the radiated noise generated by the MOSFETs 10p and 10n. A magnitude of a parasitic capacitance is dependent on a chip size, so that, when the IGBTs 20p and 20n having greater sizes are connected in parallel with the respective MOSFETs 10p and 10n, capacitances of the snubber capacitors (parasitic capacitances C_{CE}) increase to produce an effect of sufficiently reducing the radiated noise.

In the present embodiment, the unipolar switching element and the bipolar switching element are turned on at the same timing and are turned off at the same timing. That is to say, the unipolar switching element and the bipolar switching element are simultaneously turned on and turned off. In this case, the HVIC 30p and the LVIC 30n are not required to perform complex control. This prevents an increase in complexity and size of the HVIC 30p and the LVIC 30n, contributing to reduction in size of the semiconductor device.

The semiconductor device according to Embodiment 1 is only required to at least include the parallel circuit of the unipolar switching element (the MOSFET 10p or the MOSFET 10n) and the bipolar switching element (the IGBT 20p or the IGBT 20n). The other elements, such as the HVIC 30p, the LVIC 30n, and the freewheeling diodes FWD, may be built in the semiconductor device or may be externally attached to the semiconductor device.

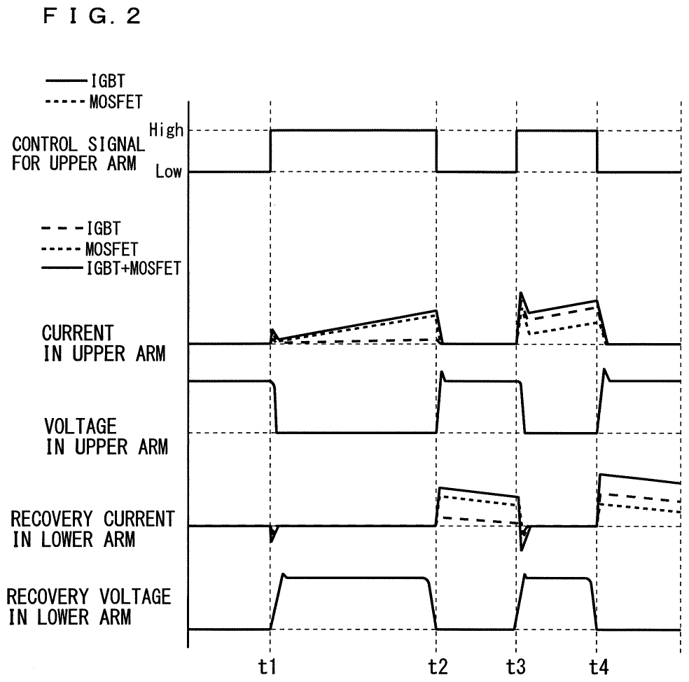

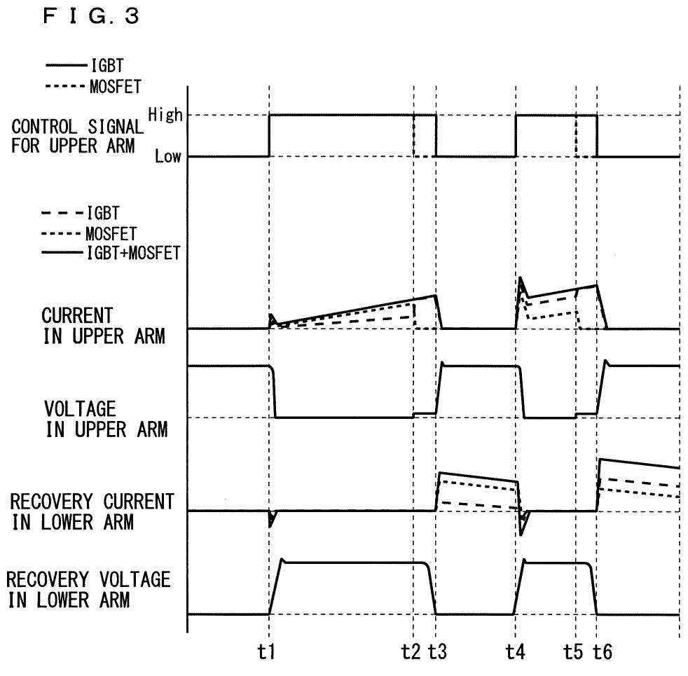

FIG. 2 is a sequence diagram showing results of a double pulse test of the semiconductor device according to Embodiment 1. FIG. 2 representatively shows results of the test of the MOSFET 10p and the IGBT 20p of the upper arm. In the double pulse test shown in FIG. 2, a test to turn on the MOSFET 10p and the IGBT 20p by a first pulse (test including a time period from time t1 to time t2) is a test in a low current range, and a test to turn on the MOSFET 10p and the IGBT 20p by a second pulse (test including a time period from time t3 to time t4) is a test in a high current range. In FIG. 2, a dotted line and a solid line in a sequence diagram “CONTROL SIGNAL FOR UPPER ARM” are respectively a graph for the MOSFET 10p and a graph for the IGBT 20p. A dotted line, a dashed line, and a solid line in each of sequence diagrams “CURRENT IN UPPER ARM” and “VOLTAGE IN UPPER ARM” are respectively a graph for the MOSFET 10p, a graph for the IGBT 20p, and a graph for the upper arm as a whole. A dotted line, a dashed line, and a solid line in each of sequence diagrams “RECOVERY CURRENT IN LOWER ARM” and “RECOVERY VOLTAGE IN LOWER ARM” are respectively a graph for the MOSFET 10n, a graph for the IGBT 20n, and a graph for the lower arm as a whole. The same applies to FIGS. 3 to 6 shown below.

At time t1 or time t3, control signals input from the HVIC 30p into the MOSFET 10p and the IGBT 20p are each changed to an H (a high) level, and the MOSFET 10p and the IGBT 20p are simultaneously turned on. In this case, although the MOSFET 10p is turned on at a high rate, the parasitic capacitance C_{CE} of the IGBT 20p having a greater size functions as a snubber capacitor, so that dI/dt and dV/dt are low to produce the effect of reducing the radiated noise. When both the MOSFET 10p and the IGBT 20p are turned on, a current flowing through the upper arm is diverted into the MOSFET 10p and the IGBT 20p, so that an on voltage of the upper arm is reduced to produce an effect of reducing loss.

Although a recovery current and a recovery voltage are generated in the lower arm when the upper arm is turned on, the parasitic capacitance C_{DS} of the MOSFET 10n and the parasitic capacitance C_{CE} of the IGBT 20n of the lower arm function as snubber capacitors, so that dV/dt of the recovery voltage is low to produce the effect of reducing the radiated noise. Furthermore, the parasitic capacitance C_{DS} of the MOSFET 10n and the parasitic capacitance C_{CE} of the IGBT 20n reduce a surge voltage generated in the lower arm, contributing to reduction in loss (although the recovery current slightly increases, the amount of loss reduced due to reduction in surge voltage is greater than the amount of loss increased by the recovery current).

At time t2 or time t4, the control signals input into the MOSFET 10p and the IGBT 20p are each changed to an L (a low) level, and the MOSFET 10p and the IGBT 20p are simultaneously turned off.

As described above, according to the semiconductor device according to Embodiment 1, contribution to reduction in loss, radiated noise, and size of the semiconductor device is enabled.

### Embodiment 2

In Embodiment 2, the unipolar switching element and the bipolar switching element constituting the parallel circuit are turned off at different timings. Specifically, the unipolar switching element and the bipolar switching element are simultaneously turned on, and the unipolar switching element is turned off and then the bipolar switching element is turned off. Although complex control is required compared with that in Embodiment 1, a difference in timing of turn-off is constant, so that an increase in complexity and size of the HVIC 30p and the LVIC 30n is suppressed compared with that in the above-mentioned technology disclosed in Japanese Patent Application Laid-Open No. 2017-228912.

FIG. 3 is a sequence diagram showing results of the double pulse test of a semiconductor device according to Embodiment 2. FIG. 3 representatively shows results of the test of the MOSFET 10p and the IGBT 20p of the upper arm. In the double pulse test shown in FIG. 3, a test to turn on the MOSFET 10p and the IGBT 20p by a first pulse (test including a time period from time t1 to time t3) is a test in a low current range, and a test to turn on the MOSFET 10p and the IGBT 20p by a second pulse (test including a time period from time t4 to time t6) is a test in a high current range.

At time t1 or time t4, the control signals input from the HVIC 30p into the MOSFET 10p and the IGBT 20p are each changed to the H level, and the MOSFET 10p and the IGBT 20p are simultaneously turned on. In this case, although the MOSFET 10p is turned on at a high rate, the parasitic capacitance C_{CE} of the IGBT 20p having a greater size functions as a snubber capacitor, so that dI/dt and dV/dt are low to produce the effect of reducing the radiated noise. When both the MOSFET 10p and the IGBT 20p are turned on, the current flowing through the upper arm is diverted into the MOSFET 10p and the IGBT 20p, so that the on voltage of the upper arm is reduced to produce the effect of reducing loss.

Although the recovery current and the recovery voltage are generated in the lower arm when the upper arm is turned on, the parasitic capacitance C_{DS} of the MOSFET 10n and the parasitic capacitance C_{CE} of the IGBT 20n of the lower arm function as snubber capacitors, so that dV/dt of the recovery voltage is low to produce the effect of reducing the radiated noise. Furthermore, the parasitic capacitance C_{DS} of the MOSFET 10n and the parasitic capacitance C_{CE} of the IGBT 20n reduce the surge voltage generated in the lower arm, contributing to reduction in loss (although the recovery current slightly increases, the amount of loss reduced due to reduction in surge voltage is greater than the amount of loss increased by the recovery current).

At time t2 or time t5, the control signal input into the MOSFET 10p is changed to the L level, and the control signal input into the IGBT 20p is maintained at the H level. Thus, the MOSFET 10p is turned off, and the IGBT 20p is maintained on.

Then, at time t3 or time t6, the control signal input into the IGBT 20p is changed to the L level, and the IGBT 20p is turned off. In this case, the parasitic capacitance CDS of the MOSFET 10p functions as a snubber capacitor, so that dV/dt and dI/dt are low to produce the effect of reducing the radiated noise. The parasitic capacitance C_{DS} of the MOSFET 10p also reduces the surge voltage generated upon turn-on of the IGBT 20p to thereby produce the effect of reducing loss.

As described above, also in Embodiment 2, the effect of reducing loss, the radiated noise, and the size of the semiconductor device can be produced. In particular, the effect of reducing the radiated noise attributable to dI/dt and dV/dt at turn-off is greater than that in Embodiment 1.

### Embodiment 3

In Embodiment 3, the unipolar switching element and the bipolar switching element constituting the parallel circuit are turned on at different timings. Specifically, the bipolar switching element is turned on and then the unipolar switching element is turned on, and the unipolar switching element and the bipolar switching element are simultaneously turned off. Although complex control is required compared with that in Embodiment 1, a difference in timing of turn-on is constant, so that the increase in complexity and size of the HVIC 30p and the LVIC 30n is suppressed compared with that in the above-mentioned technology disclosed in Japanese Patent Application Laid-Open No. 2017-228912.

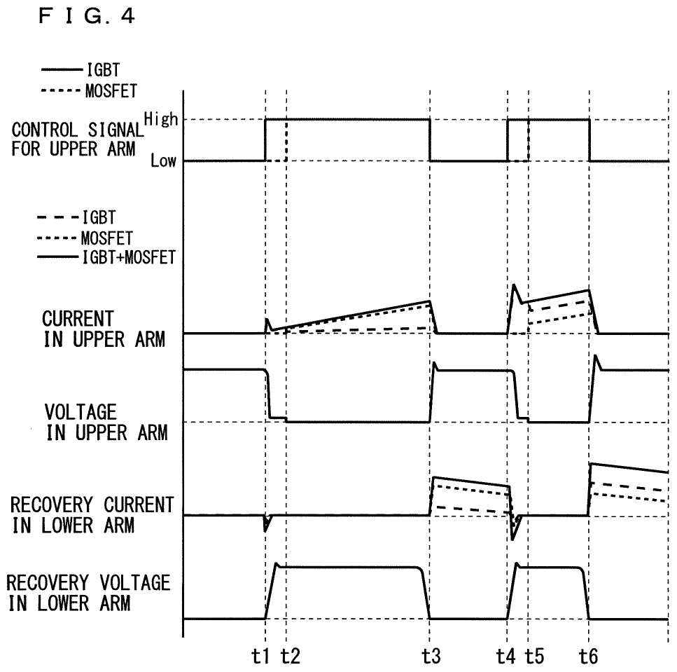

FIG. 4 is a sequence diagram showing results of the double pulse test of a semiconductor device according to Embodiment 3. FIG. 4 representatively shows results of the test of the MOSFET 10p and the IGBT 20p of the upper arm. In the double pulse test shown in FIG. 4, a test to turn on the MOSFET 10p and the IGBT 20p by a first pulse (test including a time period from time t1 to time t3) is a test in a low current range, and a test to turn on the MOSFET 10p and the IGBT 20p by a second pulse (test including a time period from time t4 to time t6) is a test in a high current range.

At time t1 or time t4, the control signal input from the HVIC 30p into the MOSFET 10p is maintained at the L level, and the control signal input from the HVIC 30p into the IGBT 20p is changed from the L level to the H level. Thus, the MOSFET 10p is maintained off, and the IGBT 20p is turned on. The IGBT 20p has a lower turn-on rate than the MOSFET 10p, so that dI/dt at turn-on is low to produce the effect of reducing the radiated noise.

Although the recovery current and the recovery voltage are generated in the lower arm when the upper arm is turned on, the parasitic capacitance C_{DS} of the MOSFET 10n and the parasitic capacitance C_{CE} of the IGBT 20n of the lower arm function as snubber capacitors, so that dV/dt of the recovery voltage is low to produce the effect of reducing the radiated noise. Furthermore, the parasitic capacitance CDS of the MOSFET 10n and the parasitic capacitance C_{CE} of the IGBT 20n reduce the surge voltage generated in the lower arm, contributing to reduction in loss (although the recovery current slightly increases, the amount of loss reduced due to reduction in surge voltage is greater than the amount of loss increased by the recovery current).

Then, at time t2 or time t5, the control signal input into the MOSFET 10p is changed to the H level, and the MOSFET 10p is turned on. When both the MOSFET 10p and the IGBT 20p are turned on, the current flowing through the upper arm is diverted into the MOSFET 10p and the IGBT 20p, so that the on voltage of the upper arm is reduced to produce the effect of reducing loss.

At time t3 or time t6, the control signals input into the MOSFET 10p and the IGBT 20p are each changed to the L level, and the MOSFET 10p and the IGBT 20p are simultaneously turned off.

As described above, also in Embodiment 3, the effect of reducing loss, the radiated noise, and the size of the semiconductor device can be produced. In particular, the effect of reducing the radiated noise attributable to dI/dt and dV/dt at turn-on is greater than that in Embodiment 1.

### Embodiment 4

In Embodiment 4, the unipolar switching element and the bipolar switching element constituting the parallel circuit are turned on at different timings and are turned off at different timings. Specifically, the bipolar switching element is turned on and then the unipolar switching element is turned on as in Embodiment 3, and the unipolar switching element is turned off and then the bipolar switching element is turned off as in Embodiment 2. Although complex control is required compared with that in Embodiment 1, a difference in timing of turn-on and a difference in timing of turn-off are each constant, so that the increase in complexity and size of the HVIC 30p and the LVIC 30n is suppressed compared with that in the above-mentioned technology disclosed in Japanese Patent Application Laid-Open No. 2017-228912.

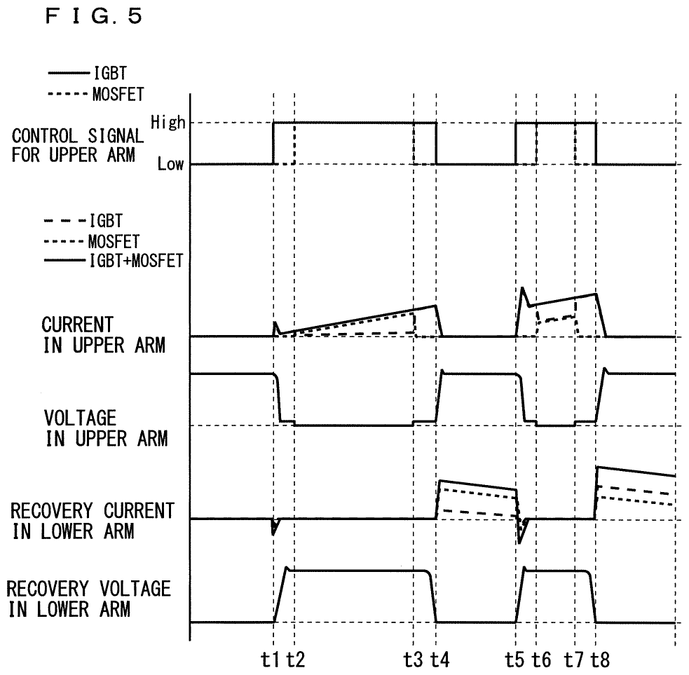

FIG. 5 is a sequence diagram showing results of the double pulse test of a semiconductor device according to Embodiment 4. FIG. 5 representatively shows results of the test of the MOSFET 10p and the IGBT 20p of the upper arm. In the double pulse test shown in FIG. 5, a test to turn on the MOSFET 10p and the IGBT 20p by a first pulse (test including a time period from time t1 to time t4) is a test in a low current range, and a test to turn on the MOSFET 10p and the IGBT 20p by a second pulse (test including a time period from time t5 to time t8) is a test in a high current range.

At time t1 or time t5, the control signal input from the HVIC 30p into the MOSFET 10p is maintained at the L level, and the control signal input from the HVIC 30p into the IGBT 20p is changed from the L level to the H level. Thus, the MOSFET 10p is maintained off, and the IGBT 20p is turned on. The IGBT 20p has a lower turn-on rate than the MOSFET 10p, so that dI/dt at turn-on is low to produce the effect of reducing the radiated noise.

Although the recovery current and the recovery voltage are generated in the lower arm when the upper arm is turned on, the parasitic capacitance CDS of the MOSFET 10n and the parasitic capacitance C_{CE} of the IGBT 20n of the lower arm function as snubber capacitors, so that dV/dt of the recovery voltage is low to produce the effect of reducing the radiated noise. Furthermore, the parasitic capacitance CDS of the MOSFET 10n and the parasitic capacitance C_{CE} of the IGBT 20n reduce the surge voltage generated in the lower arm, contributing to reduction in loss (although the recovery current slightly increases, the amount of loss reduced due to reduction in surge voltage is greater than the amount of loss increased by the recovery current).

Then, at time t2 or time t6, the control signal input into the MOSFET 10p is changed to the H level, and the MOSFET 10p is turned on. When both the MOSFET 10p and the IGBT 20p are turned on, the current flowing through the upper arm is diverted into the MOSFET 10p and the IGBT 20p, so that the on voltage of the upper arm is reduced to produce the effect of reducing loss.

At time t3 or time t7, the control signal input into the MOSFET 10p is changed to the L level, and the control signal input into the IGBT 20p is maintained at the H level. Thus, the MOSFET 10p is turned off, and the IGBT 20p is maintained on.

Then, at time t4 or time t8, the control signal input into the IGBT 20p is changed to the L level, and the IGBT 20p is turned off. In this case, the parasitic capacitance CDS of the MOSFET 10p functions as a snubber capacitor, so that dV/dt and dI/dt are low to produce the effect of reducing the radiated noise. The parasitic capacitance CDS of the MOSFET 10p also reduces the surge voltage generated upon turn-on of the IGBT 20p to thereby produce the effect of reducing loss.

As described above, in Embodiment 5, the effect of reducing loss, the radiated noise, and the size of the semiconductor device can be produced by the action in both of Embodiments 2 and 3. In particular, in the present embodiment, the bipolar switching element mainly performs switching between on and off of the parallel circuit, so that the radiated noise is generated mainly by switching performed by the bipolar switching element, and the unipolar switching element generates little radiated noise. The radiated noise generated by the unipolar switching element tends to be small in the low current range, and the radiated noise generated by the bipolar switching element tends to be small in the high current range, so that application in a range in which the current is higher than a particular value is effective in the present embodiment.

### Embodiment 5

In Embodiment 5, the unipolar switching element and the bipolar switching element are turned on and turned off in reverse order compared with that in Embodiment 4. Specifically, the unipolar switching element is turned on and then the bipolar switching element is turned on, and the bipolar switching element is turned off and then the unipolar switching element is turned off. A difference in timing of turn-on and a difference in timing of turn-off are each constant also in the present embodiment, so that the increase in complexity and size of the HVIC 30p and the LVIC 30n is suppressed compared with that in the above-mentioned technology disclosed in Japanese Patent Application Laid-Open No. 2017-228912.

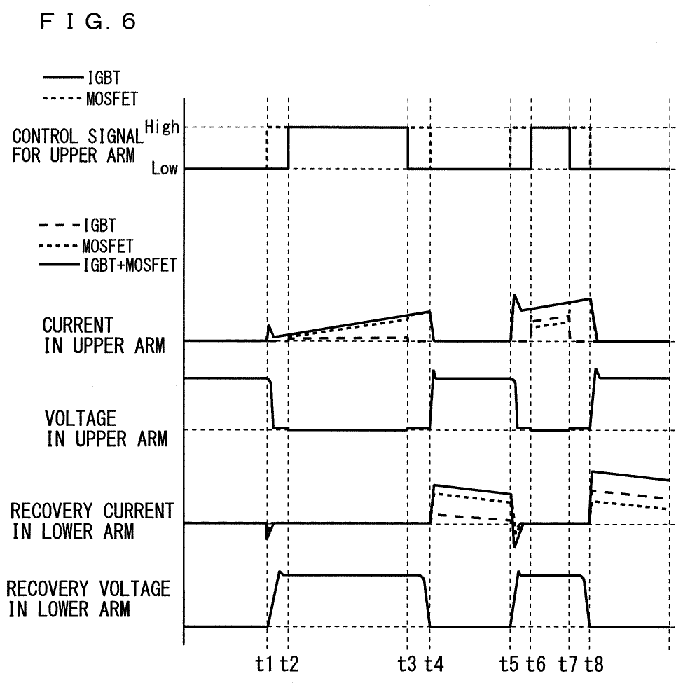

FIG. 6 is a sequence diagram showing results of the double pulse test of a semiconductor device according to Embodiment 5. FIG. 6 representatively shows results of the test of the MOSFET 10p and the IGBT 20p of the upper arm. In the double pulse test shown in FIG. 6, a test to turn on the MOSFET 10p and the IGBT 20p by a first pulse (test including a time period from time t1 to time t4) is a test in a low current range, and a test to turn on the MOSFET 10p and the IGBT 20p by a second pulse (test including a time period from time t5 to time t8) is a test in a high current range.

At time t1 or time t5, the control signal input from the HVIC 30p into the MOSFET 10p is changed from the L level to the H level, and the control signal input from the HVIC 30p into the IGBT 20p is maintained at the L level. Thus, the MOSFET 10p is turned on, and the IGBT 20p is maintained off. Although the MOSFET 10p is turned on at a high rate, the parasitic capacitance C_{CE} of the IGBT 20p having a greater size functions as a snubber capacitor, so that dI/dt and dV/dt are low to produce the effect of reducing the radiated noise.

Although the recovery current and the recovery voltage are generated in the lower arm when the upper arm is turned on, the parasitic capacitance CDS of the MOSFET 10n and the parasitic capacitance C_{CE} of the IGBT 20n of the lower arm function as snubber capacitors, so that dV/dt of the recovery voltage is low to produce the effect of reducing the radiated noise. Furthermore, the parasitic capacitance CDS of the MOSFET 10n and the parasitic capacitance C_{CE} of the IGBT 20n reduce the surge voltage generated in the lower arm, contributing to reduction in loss (although the recovery current slightly increases, the amount of loss reduced due to reduction in surge voltage is greater than the amount of loss increased by the recovery current).

Then, at time t2 or time t6, the control signal input into the IGBT 20p is changed to the H level, and the IGBT 20p is turned on. When both the MOSFET 10p and the IGBT 20p are turned on, the current flowing through the upper arm is diverted into the MOSFET 10p and the IGBT 20p, so that the on voltage of the upper arm is reduced to produce the effect of reducing loss.

At time t3 or time t7, the control signal input into the MOSFET 10p is maintained at the H level, and the control signal input into the IGBT 20p is changed to the L level. Thus, the MOSFET 10p is maintained on, and the IGBT 20p is turned off.

Then, at time t4 or time t8, the control signal input into the MOSFET 10p is changed to the L level, and the MOSFET 10p is turned off. In this case, the parasitic capacitance C_{CE} of the IGBT 20p functions as a snubber capacitor, so that dV/dt and dI/dt are low to produce the effect of reducing the radiated noise. The parasitic capacitance C_{CE} of the IGBT 20p also reduces the surge voltage generated upon turn-on of the MOSFET 10p to thereby produce the effect of reducing loss.

As described above, also in Embodiment 5, the effect of reducing loss, the radiated noise, and the size of the semiconductor device can be produced. In particular, in the present embodiment, the unipolar switching element mainly performs switching between on and off of the parallel circuit, so that the radiated noise is generated mainly by switching performed by the unipolar switching element, and the bipolar switching element generates little radiated noise. The radiated noise generated by the unipolar switching element tends to be small in the low current range, and the radiated noise generated by the bipolar switching element tends to be small in the high current range, so that application in a range in which the current is lower than a particular value is effective in the present embodiment.

### Embodiment 6

A base material for the bipolar switching element and the unipolar switching element may be silicon (Si) as before and may be a wide bandgap semiconductor, such as silicon carbide (SiC), gallium nitride (GaN), and diamond. The bipolar switching element and the unipolar switching element each formed of the wide bandgap semiconductor contribute to reduction in size of the semiconductor device.

In particular, when the unipolar switching element is formed of the wide bandgap semiconductor, an increase in loss can be prevented if the unipolar switching element has a smaller chip size than the bipolar switching element.

When the unipolar switching element is a MOSFET formed of SiC (an SiC-MOSFET), and the bipolar switching element is an IGBT, an effect as described below will be produced. The SiC-MOSFET has negative temperature characteristics, that is, characteristics in that a current flows more easily as a temperature increases. In the high current range, the amount of current diverted into the IGBT increases, so that the IGBT generates a larger amount of heat than the SiC-MOSFET. When the temperature of the semiconductor device increases due to heat generation of the IGBT, however, the amount of current diverted into the SiC-MOSFET having the negative temperature characteristics increases, and, in response to this, the amount of current diverted into the IGBT decreases, so that heat generation of the IGBT is suppressed to prevent destruction of the IGBT. When the amount of current diverted into the SiC-MOSFET increases, the amount of heat generated by the SiC-MOSFET increases, but thermal destruction does not occur because the SiC-MOSFET has high heat conductivity.

Embodiments can freely be combined with each other and can be modified or omitted as appropriate.

### Appendices

Various aspects of the present disclosure will collectively be described below as appendices.

### Appendix 1

A semiconductor device comprising
a parallel circuit of a unipolar switching element and a bipolar switching element, wherein
the bipolar switching element has a greater chip size than the unipolar switching element.

### Appendix 2

The semiconductor device according to Appendix 1, further comprising
a control circuit to drive the unipolar switching element and the bipolar switching element, wherein
the control circuit
   simultaneously turns on the bipolar switching element and the unipolar switching element when turning on the unipolar switching element and the bipolar switching element, and
   simultaneously turns off the bipolar switching element and the unipolar switching element when turning off the unipolar switching element and the bipolar switching element.

### Appendix 3

The semiconductor device according to Appendix 1, further comprising
a control circuit to drive the unipolar switching element and the bipolar switching element, wherein
the control circuit
   simultaneously turns on the bipolar switching element and the unipolar switching element when turning on the unipolar switching element and the bipolar switching element, and
   turns off the unipolar switching element and then turns off the bipolar switching element when turning off the unipolar switching element and the bipolar switching element.

### Appendix 4

The semiconductor device according to Appendix 1, further comprising
a control circuit to drive the unipolar switching element and the bipolar switching element, wherein
the control circuit
   turns on the bipolar switching element and then turns on the unipolar switching element when turning on the unipolar switching element and the bipolar switching element, and
   simultaneously turns off the bipolar switching element and the unipolar switching element when turning off the unipolar switching element and the bipolar switching element.

### Appendix 5

The semiconductor device according to Appendix 1, further comprising
a control circuit to drive the unipolar switching element and the bipolar switching element, wherein
the control circuit
   turns on the bipolar switching element and then turns on the unipolar switching element when turning on the unipolar switching element and the bipolar switching element, and
   turns off the unipolar switching element and then turns off the bipolar switching element when turning off the unipolar switching element and the bipolar switching element.

### Appendix 6

The semiconductor device according to Appendix 1, further comprising
a control circuit to drive the unipolar switching element and the bipolar switching element, wherein
the control circuit
   turns on the unipolar switching element and then turns on the bipolar switching element when turning on the unipolar switching element and the bipolar switching element, and
   turns off the bipolar switching element and then turns off the unipolar switching element when turning off the unipolar switching element and the bipolar switching element.

### Appendix 7

The semiconductor device according to any one of Appendices 1 to 6, wherein
the unipolar switching element is formed of a wide bandgap semiconductor.

### Appendix 8

The semiconductor device according to Appendix 7, wherein
the unipolar switching element is a MOSFET formed of SiC, and
the bipolar switching element is an IGBT.

While the disclosure has been shown and described in detail, the foregoing description is in all aspects illustrative and not restrictive. It is therefore understood that numerous modifications and variations can be devised.

What is claimed is:

1. A semiconductor device comprising
a parallel circuit of a unipolar switching element and a bipolar switching element, wherein
the bipolar switching element has a greater chip size than the unipolar switching element.

2. The semiconductor device according to claim 1, further comprising
a control circuit to drive the unipolar switching element and the bipolar switching element, wherein
the control circuit
simultaneously turns on the bipolar switching element and the unipolar switching element when turning on the unipolar switching element and the bipolar switching element, and
simultaneously turns off the bipolar switching element and the unipolar switching element when turning off the unipolar switching element and the bipolar switching element.

3. The semiconductor device according to claim 1, further comprising
a control circuit to drive the unipolar switching element and the bipolar switching element, wherein
the control circuit
simultaneously turns on the bipolar switching element and the unipolar switching element when turning on the unipolar switching element and the bipolar switching element, and
turns off the unipolar switching element and then turns off the bipolar switching element when turning off the unipolar switching element and the bipolar switching element.

4. The semiconductor device according to claim 1, further comprising
a control circuit to drive the unipolar switching element and the bipolar switching element, wherein
the control circuit
turns on the bipolar switching element and then turns on the unipolar switching element when turning on the unipolar switching element and the bipolar switching element, and
simultaneously turns off the bipolar switching element and the unipolar switching element when turning off the unipolar switching element and the bipolar switching element.

5. The semiconductor device according to claim 1, further comprising
a control circuit to drive the unipolar switching element and the bipolar switching element, wherein
the control circuit
turns on the bipolar switching element and then turns on the unipolar switching element when turning on the unipolar switching element and the bipolar switching element, and
turns off the unipolar switching element and then turns off the bipolar switching element when turning off the unipolar switching element and the bipolar switching element.

6. The semiconductor device according to claim 1, further comprising
a control circuit to drive the unipolar switching element and the bipolar switching element, wherein
the control circuit
turns on the unipolar switching element and then turns on the bipolar switching element when turning on the unipolar switching element and the bipolar switching element, and
turns off the bipolar switching element and then turns off the unipolar switching element when turning off the unipolar switching element and the bipolar switching element.

7. The semiconductor device according to claim 1, wherein
the unipolar switching element is formed of a wide bandgap semiconductor.

8. The semiconductor device according to claim 7, wherein
the unipolar switching element is a MOSFET formed of SiC, and
the bipolar switching element is an IGBT.

9. The semiconductor device according to claim 2, wherein
the unipolar switching element is formed of a wide bandgap semiconductor.

10. The semiconductor device according to claim 9, wherein
the unipolar switching element is a MOSFET formed of SiC, and
the bipolar switching element is an IGBT.

11. The semiconductor device according to claim 3, wherein
the unipolar switching element is formed of a wide bandgap semiconductor.

12. The semiconductor device according to claim 11, wherein
the unipolar switching element is a MOSFET formed of SiC, and
the bipolar switching element is an IGBT.

13. The semiconductor device according to claim 4, wherein
the unipolar switching element is formed of a wide bandgap semiconductor.

14. The semiconductor device according to claim 13, wherein
the unipolar switching element is a MOSFET formed of SiC, and
the bipolar switching element is an IGBT.

15. The semiconductor device according to claim 5, wherein
the unipolar switching element is formed of a wide bandgap semiconductor.

16. The semiconductor device according to claim 15, wherein
the unipolar switching element is a MOSFET formed of SiC, and
the bipolar switching element is an IGBT.

17. The semiconductor device according to claim 6, wherein
the unipolar switching element is formed of a wide bandgap semiconductor.

18. The semiconductor device according to claim 17, wherein
the unipolar switching element is a MOSFET formed of SiC, and
the bipolar switching element is an IGBT.
